(19) United States
(12) Patent Application Publication
(10) Pub. No.: US 2007/0074969 A1
(43) Pub. Date: Apr. 5, 2007

(54) Very long cylindrical sputtering target and method for manufacturing

(76) Inventors: Wayne R. Simpson, San Jose, CA (US); Ryan A. Scatena, Gilroy, CA (US); Thomas R. Stevenson, Gilroy, CA (US); Jaime F. Guerrero, San Jose, CA (US)

Correspondence Address: DONALD J. PAGEL, 586 NORTH FIRST STREET, SUITE 207, SAN JOSE, CA, 95112, US

(21) Appl. No.: 11/541,984

(22) Filed: Oct. 2, 2006

Related U.S. Application Data
(60) Provisional application No. 60/723,413, filed on Oct. 3, 2005.

(51) Int. Cl. C23C 14/32; C23C 14/00

(52) U.S. Cl. 204/192.1; 204/298.12

(57) ABSTRACT

The present invention includes a long cylindrical sputtering target assembly and a method for manufacturing the assembly. The long cylindrical sputtering target assembly comprises a cylindrical sputtering target having a length greater than approximately thirty-six inches and being comprised of one or more cylindrical sputtering target sections; a cylindrical backing tube; and an attachment layer, such as indium, positioned between the cylindrical sputtering target and the cylindrical backing tube for attaching the cylindrical sputtering target to the cylindrical backing tube. The method comprises the steps of preparing an outside surface of a cylindrical backing tube and/or an inside surface of one or more cylindrical sputtering target sections for bonding; bringing the cylindrical backing tube and the one or more cylindrical sputtering target sections together so that the outside surface of the cylindrical backing tube and the inside surface of the one or more cylindrical sputtering target sections are adjacent to each other but separated by a space, with the one or more cylindrical sputtering target sections having a total length greater than thirty-six inches; and filling the space with an attachment material comprised of indium while the backing tube is oriented in a vertical direction.

### BACKGROUND OF THE INVENTION

1. Technical Field

The present invention relates to a method for manufacturing a cylindrical sputtering target for use in a vacuum deposition technique and more particularly to a method for attaching a plurality of cylindrical sputtering targets to a cylindrical backing tube to make a very long cylindrical sputtering target.

2. Background Information

Sputtering is a major vacuum deposition technique used to deposit a thin film of a target material on a substrate. Many materials are capable of being sputtered and typical target materials include elemental metals (such as copper, gold, tungsten, molybdenum and aluminum etc.), alloys (such as aluminum-copper alloy, aluminum-neodymium and titanium-tungsten alloy, etc.), and compounds (such as silicon dioxide and titanium nitride, etc.). Typical substrates on which the target material is deposited include items such semiconductor devices, compact discs (CD), hard disks for use in magnetic disk drives, and optical devices such as flat panel displays.

A typical sputtering apparatus comprises a vacuum chamber inside of which are positioned the target and the substrate. The target is electrically configured to be an electrode with a large ion flux. The chamber is filled with an inert gas which ionizes when power is supplied to the target/electrode. The positively charged inert gas ions collide with the target causing atomic sized particles to be ejected from the target. The particles are then deposited on the surface of the substrate as a thin film.

Because of this electrical configuration, the target can become very hot and needs to be cooled. In a typical sputtering apparatus, the cooling is provided by a water-cooled backing member to which the target is attached by an attachment layer. In some sputtering systems, a rectangular target and backing plate are used, while in other systems, the target and backing plate are cylindrical in shape. FIG. 1 illustrates a cylindrical sputtering assembly 10 that comprises a cylindrical sputtering target 12, a cylindrical backing tube 16 and an attachment layer 20. The cylindrical sputtering target has a sputtering face 24 from which the material to be sputtered on a substrate 30 is ejected. The cylindrical sputtering target 12 can be one continuous piece of material, or it can be comprised of two or more separate pieces. The sputtering target 12 is cooled by water running through the lumen (hollow passage) inside of the backing tube 16. A magnetron (an assembly of magnets) is also positioned in the lumen of the backing tube 16 for generating magnetic flux that attracts ions in the plasma that cause target material to be sputtered onto the substrate 30. Generally, the substrate 30 is moved laterally under the cylindrical sputtering assembly 10 in the direction of the arrow 32. The cylindrical sputtering assembly 10 can be rotated in the direction of the arrow 33 so that material from the entire surface area of the sputtering face 24 is used in the sputtering process.

In the prior art, a number of materials are used in the attachment layer 20 to attach the cylindrical target 12 to the backing tube 16. However, in the prior art only relatively short cylindrical sputtering targets have been bonded. For example, in the prior art, the length “k” of the cylindrical sputtering assembly 10 shown in FIG. 1 is less than thirty-six inches (91.44 centimeters). The relatively short length of the prior art cylindrical sputtering assemblies is partially due industry requirements and also to the difficulty of bonding targets to long backing tubes.

A trend in the manufacturing of flat panel displays and other devices is to manufacture many devices on a very large substrate, much like smaller semiconductor devices are manufactured on wafers. For example, flat panel display manufacturers would like to be able to process square or rectangular flat panel display substrates having surface areas on the order of approximately 1200 square inches (7742 square centimeters) to 6000 square inches (38,700 square centimeters) or more. Some of these large substrates are currently being processed using large rectangular sputtering targets that are indium bonded to a backing plate. However, cylindrical sputtering targets long enough for use with substrates having surface areas on the order of approximately 1200 square inches or more have not previously been described.

### SUMMARY OF THE PRESENT INVENTION

Briefly, the present invention includes an elongated sputtering target assembly and a method for attaching a cylindrical sputtering target to a cylindrical backing tube to form the elongated assembly. The method comprises the steps of preparing an outside surface of a cylindrical backing tube and/or an inside surface of one or more cylindrical sputtering target sections for bonding; bringing the cylindrical backing tube and the one or more cylindrical sputtering target sections together so that the outside surface of the cylindrical backing tube and the inside surface of the one or more cylindrical sputtering target sections are adjacent to each other but separated by a space, with the one or more cylindrical sputtering target sections having a total length greater than thirty-six inches; and filling the space with an attachment material, such as indium, while the backing tube is oriented in a vertical direction. In a preferred embodiment, outside surface of a cylindrical backing tube and/or an inside surface of one or more cylindrical sputtering target sections are prepared for bonding by wetting with indium using ultrasonic energy to aide the wetting process.

The elongated sputtering target assembly comprises a cylindrical sputtering target having a length greater than approximately thirty-six inches and is comprised of one or more cylindrical sputtering target sections; a cylindrical backing tube; and an attachment layer, such as indium, positioned between the cylindrical sputtering target and the cylindrical backing tube for attaching the cylindrical sputtering target to the cylindrical backing tube.

### BRIEF DESCRIPTION OF THE SEVERAL VIEWS OF THE DRAWINGS

FIG. 1 is an isometric view of a cylindrical sputtering target assembly;

FIG. 2 is a side view of a cylindrical sputtering target assembly;

FIG. 3 is a cross-sectional view taken along the line 3-3 in FIG. 2;

FIG. 4 is an isometric view of part of a heating tube;

FIG. 5 is a cross-sectional view of a cylindrical sputtering target assembly positioned vertically during manufacturing;

FIG. 6 is an isometric view of an ultrasonic tool; and

FIG. 7 is an isometric view of another ultrasonic tool.

### DETAILED DESCRIPTION OF THE INVENTION

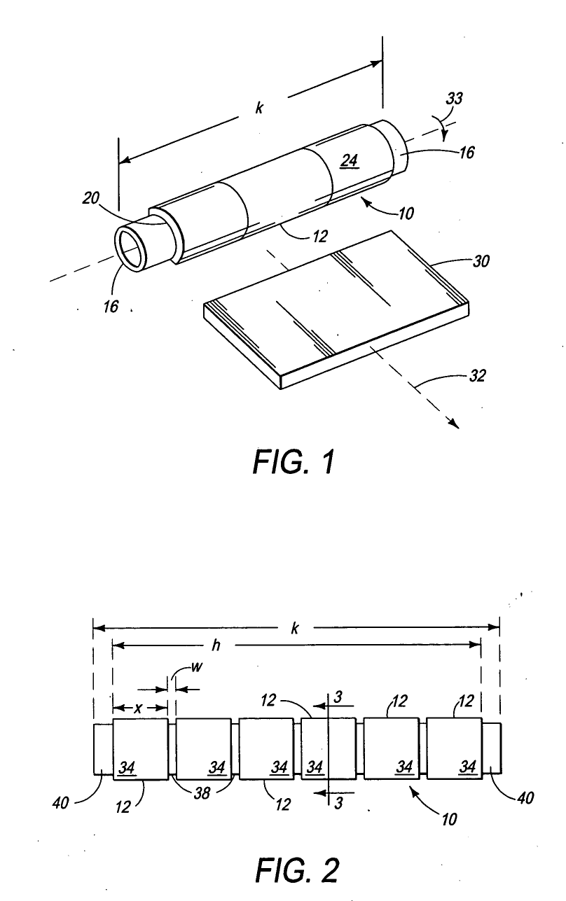

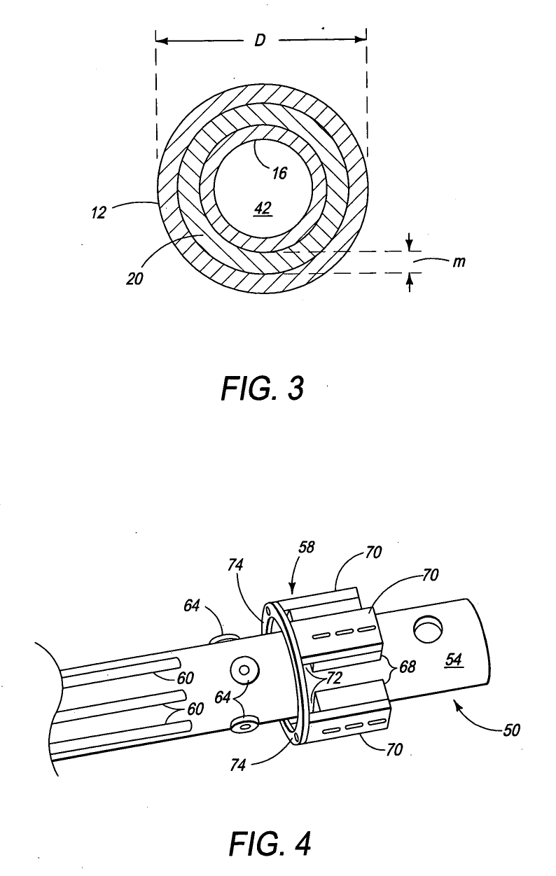

In the present invention, the cylindrical sputtering target assembly 10 shown in FIG. 1 comprises the cylindrical sputtering target 12, the cylindrical backing tube 16 and the attachment layer 20. The sputtering target 12 includes the sputtering surface 24 which is a surface from which the material to be sputtered on the substrate can be ejected when the sputtering process begins. In the present invention, the length “h” of the cylindrical sputtering target 12 (shown in FIG. 2) is greater than thirty-six inches, and more preferably is in the range of forty inches (101.6 cm) to one hundred and thirty inches (330.2 cm) or greater. Additionally, the cylindrical sputtering target 12 has an outer diameter “D” (shown in FIG. 3), but the length “h” is a more important parameter to the present invention than is the diameter “D.” For reference purposes the outer diameter “D” is usually greater than about five and one half inches (5.5 in), and more preferably is in the range of 5.5 to 9.45 inches (14 to 24 cm).

FIG. 2 illustrates that the sputtering surface 24 of the cylindrical sputtering target 12 is comprised of a plurality of individual cylindrical ring targets 34. A gap 38 exists between each pair of adjacent ring targets 34. The gap 38 has a width “w” which is on the order of approximately 0.02 inch (0.5 mm). As used herein, the length “h” of the cylindrical sputtering target 12 refers to the total length of the sputtering surface 24 in a single cylindrical sputtering assembly 10, regardless of whether the sputtering target is comprised of one piece of material or more than one piece. In other words, the length “h” includes the total of all of the lengths “x” of the individual cylindrical ring targets 34.

In FIG. 2, the length “h” is shown as including the widths “w” of the gaps 38, since the sum of the widths “w” is very small. This approximation is acceptable because the sum of the widths “w” is much smaller than the length “h.” Notwithstanding this acceptable approximation, the length “h” of the cylindrical sputtering target 12 refers to the total length of the sputtering surface 24. The length “h” is less than the length “k” of the assembly 10 because an exposed section 40 of the backing tube 16 extends beyond the last cylindrical ring target 34 on each end of the cylindrical sputtering assembly 10.

Each of the individual cylindrical ring targets 34 (also called cylindrical sputtering target sections 34) is a cylindrical piece of material comprised of a sputtering target material. The individual cylindrical ring targets 34 are hollow in the middle so as to accommodate the backing tube 16 and attachment layer 20 (shown in FIG. 3). The length “x” of the individual cylindrical ring targets 34 can be any length, but in a representative example the length “x” is approximately eight inches (20.32 cm). Additionally, the length “x” can be different for individual cylindrical ring targets 34 within a given cylindrical sputtering target 12.

By using a plurality of individual cylindrical ring targets 34 having relatively short lengths “x”, it is easier to build a long cylindrical sputtering target 12 having the length “h” greater than thirty-six inches. This is particularly true for certain sputtering materials like ceramic materials, where it is difficult (or not possible) to make a single cylindrical ring target 34 where the length “x” is greater than thirty-six inches. However, with other sputtering materials, such as metals, a single cylindrical ring target 34 having the length “x” greater than thirty-six inches could be used in the present invention.

The cylindrical sputtering target 12 (and hence the individual cylindrical ring targets 34) can be comprised of many materials. Typical sputtering target materials include elemental materials (such as silver, silicon, copper, gold, tungsten, molybdenum and aluminum etc.), alloys (such as aluminum-copper alloy, aluminum-neodymium, indium-tin-oxide and titanium-tungsten alloy, etc.), and compounds (such as silicon dioxide, silicon carbide, ceramic materials and titanium nitride, etc.).

FIG. 3 illustrates that the attachment layer 20 is positioned between the cylindrical sputtering target 12 and the backing tube 16, and that the attachment layer 20 has a width “m” that is preferably on the order of approximately 0.015 inch (0.38 mm), although other widths can be used. The backing tube 16 is a long hollow cylindrical tube that is strong enough to mechanically support the cylindrical sputtering target 12. The backing tube 16 includes a lumen 42 through which water or some other fluid can flow to act as a coolant for the cylindrical sputtering target 12. In a preferred embodiment, the backing tube 16 comprises stainless steel or titanium tube, but other materials such as aluminum alloys, copper or copper alloys can be used.

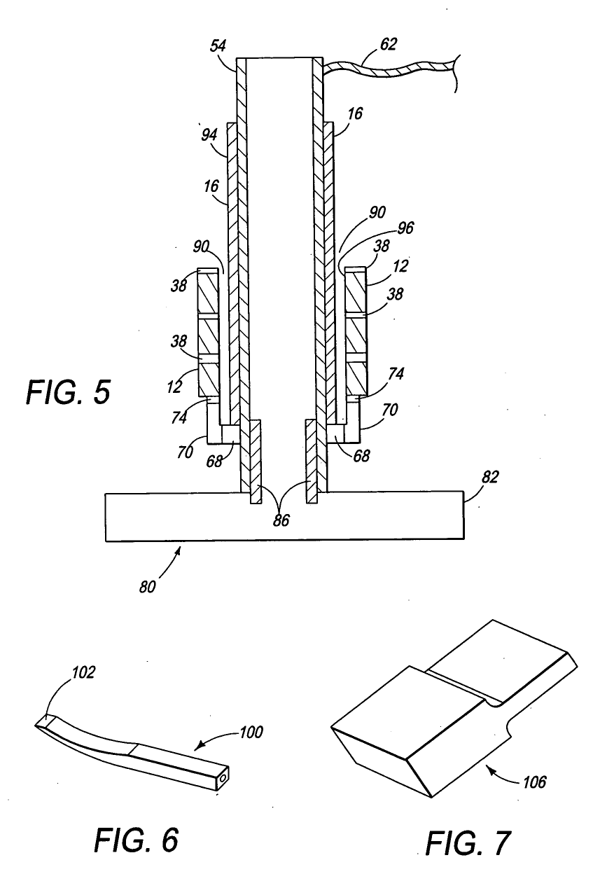

FIG. 4 illustrates a heating tube 50 that is used in manufacturing the cylindrical sputtering target assembly 10. The heating tube 50 comprises a hollow cylindrical metal heating tube 54, which is preferably comprised of aluminum, a positioning fixture 58, a heating element 60 to provide the heat source for the heating tube 54, and a plurality of spacers 64. During the manufacturing process, the heating tube 54 is inserted into the lumen 42 of the backing tube 16 to provide a heat source to the backing tube 16. In a preferred embodiment, the heating element 60 comprises a plurality of tubular heaters (e.g. eight tubular heaters, 29 watts/inch) that are positioned around the outside of the tube 54 extending parallel to the length of the tube 54. Alternatively, the heating element 60 could comprise another type of heat source, such as a wire coil wrapped around the tube 54. An electrical lead 62 (shown in FIG. 5) is electrically connected between the heating element 60 and control circuitry to provide electrical power to the heating element 60. The spacers 64 create a space between the outside of the heating tube 54 and the inside of the backing tube 16 for the heating element 60 to sit in.

The positioning fixture 58 is firmly attached to the heating tube 54 (e.g. with bolts) and is used to align the ring targets 34 on the backing tube 16 during manufacturing. The fixture 58 comprises a backing tube stop 68 and a target stop 70 which is longer than the backing tube stop 68. The difference in length creates a space 72 into which the backing tube stop 68 can fit while it rests on the backing tube stop 68. The first ring target 34 in the cylindrical sputtering target assembly 10 will rest on a surface 74 of the target stop 70 (see FIG. 5).

FIG. 5 illustrates an assembly stand 80 that is used in manufacturing the cylindrical sputtering target assembly 10. The assembly stand 80 is preferably comprised of steel, but other materials could be used, and comprises a base 82 and a vertical fixture 86. During part of the manufacturing process, the vertical fixture 86 is inserted into the hollow inside of the heating tube 54 to hold the heating tube 54 and backing tube 16 in a vertical position while the attachment layer 20 is formed. The backing tube 16 is positioned with one end resting on the backing tube stop 68. Either while the backing tube 16 is positioned vertically on the stand 80, or earlier while the backing tube 16 is still horizontal, the ring targets 12 (preferably in groups of three) are slid over the backing tube 16 until the first ring target 12 rests on the surface 74 of the target stop 70. At this point, a slot (space) 90 exists between the ring targets 12 and the backing tube 16 which will be filled with an attachment material, as is explained later. FIG. 5 also shows an outside surface 94 of the backing tube 16 and an inside surface 96 of the cylindrical sputtering target 12.

FIG. 6 illustrates an ultrasonic horn 100 that is used in a preferred embodiment for wetting the inside surface 96 of the cylindrical sputtering target 12 with indium. A face 102 on the ultrasonic horn 100 is used to spread the indium as well as to transmit ultrasonic energy into the indium while it is being spread. Similarly, FIG. 7 illustrates an ultrasonic horn 106 that is used in a preferred embodiment for wetting the outside surface 94 of the backing tube 16 with indium. Other shaped ultrasonic horns can be substituted for the horns 100 and 106, and other techniques can be used to spread and/or wet the surfaces 96 and 94 with indium.

The apparatus of the present invention comprises a cylindrical sputtering target 12 having a cylindrical sputtering surface 24 that is longer than thirty-six inches that is used to sputter substrates with large surface areas. Since the cylindrical sputtering target 12 is cylindrical in shape (in the preferred embodiment, a finite section of a right circular cylinder), the area (A) of the sputtering surface 24 is given by the equation: A=2πr(r+h), where r is the radius of the cylinder (D/2 in FIG. 3) and h is the length of the cylinder (see FIG. 2). Thus, the surface area of the sputtering surface 24 is dependent on both the outer diameter of the cylinder and the length of the cylinder. However, in practice it is the length (h) of the cylindrical sputtering target 12 that is of interest because it is the length (h) that allows the cylindrical sputtering target 12 to provide sputtering coverage for a large substrate. Hence the length (h) of the cylindrical sputtering target 12 is the critical parameter, and in the present invention the cylindrical sputtering target 12 has a length (h) that is greater than thirty-six inches (91.44 cm). More preferably, the length (h) is in the range of forty inches (101.6 cm) to one hundred and thirty inches (330.2 cm), but can also be greater than one hundred and thirty inches. In a representative embodiment, the length (h) is approximately seventy-two inches (183 cm).

In a preferred embodiment, the cylindrical sputtering target 12 is attached to the cylindrical backing tube 16 by the attachment layer 20 that comprises indium. Most preferably, the indium is 99.99% pure or better. However, other materials can be used as the attachment layer 20 such as indium alloys (including indium/tin alloys), tin or an elastomer. The elastomer may comprises a silicone elastomer, including a poly(dimethylsiloxane) elastomer, such as Sylgard® 184 brand silicone elastomer sold by Dow Corning. Other types of suitable elastomers can be used as the attachment layer 20 such as polymers compatible with a vacuum environment that can withstand temperatures above 50° C. while maintaining a suitably strong bond between the sputtering target and the backing plate and adequately transferring heat from the sputtering target to the backing plate. Specific types of polymers that can be used include polyimide, polyketone, polyetherketone, polyether sulfone, polyethylene terephthalate, and fluroethylene propylene copolymers. Flexible epoxy or rubber can also be used Other silicone elastomers that can be used include the products marketed as General Electric RTV 31 and General Electric RTV 615 brand silicone elastomers.

In a preferred embodiment, the method for attaching the cylindrical sputtering target 12 to the cylindrical backing tube 16 comprises the steps of preparing an outside surface of the cylindrical backing tube 16 and/or an inside surface of one or more cylindrical sputtering target sections 34 for bonding; bringing the cylindrical backing tube and the one or more cylindrical sputtering target sections together so that the outside surface of the cylindrical backing tube and the inside surface of the one or more cylindrical sputtering target sections are adjacent to each other but separated by a space (slot 90), with the one or more cylindrical sputtering target sections having a total length greater than thirty-six inches; and filling the space with an attachment material while the backing tube is oriented in a vertical direction. The attachment material should sufficiently strong to keep the cylindrical sputtering target attached to the cylindrical backing tube during a sputtering process.

The step of preparing an outside surface of the cylindrical backing tube 16 and/or an inside surface of one or more cylindrical sputtering target sections 34 for bonding can mean wetting the surfaces with a bonding material, such as a material comprised of indium; or it can mean cleaning the surface such as by sandblasting and/or wiping the surface with a solvent. If an elastomer or other material that bonds adequately to both of these surfaces is used as the attachment layer 20, then the preparation typically would not involve wetting.

In a more preferred embodiment, the method of the present invention comprises the steps of wetting an outside surface of the backing tube 16 and an inside surface of the cylindrical sputtering target 12 with indium, where the cylindrical sputtering target comprises one or more cylindrical sputtering target sections 34, has a length greater than approximately thirty-six inches and ultrasonic energy is used to help wet the relevant surfaces. The backing tube 16 is then positioned on a structure such as the assembly stand 80 that holds the backing tube in a vertical orientation. The cylindrical sputtering target 12 is positioned around the backing tube 16 by assembling groups of three individual cylindrical sputtering target sections 34 and positioning them around the backing tube 16 with a slot 90 between the backing tube 16 and the cylindrical sputtering target 12, and then filling the slot 90 with indium.

This process is repeated by positioning additional cylindrical sputtering targets 34 around the backing tube 16 with a slot 90 being maintained between the backing tube 16 and the cylindrical sputtering targets 34, and then filling the slot 90 with indium, until the length of the sputtering surface 24 is greater than approximately thirty-six inches.

Preferably, ultrasonic energy is used in the steps of wetting the outside surface of the backing tube 16 and the inside surface of the cylindrical sputtering target 12 with indium, such as ultrasonic energy at a frequency of 20 KHz and a power of 700 watts. However, other energies and/or powers, and other wetting techniques can be used, such as metalizing the outside surface of the backing tube 16 and the inside surface of the cylindrical sputtering target 12, using a sputtering or other deposition technique; or by plating a metal layer onto these surfaces (e.g. a chromium-nickel-silver layer). The purpose of wetting is to create a surface that the attachment layer 20 can adhere or bond to. It is thought that using ultrasonic energy when wetting the outside surface of the backing tube 16 and the inside surface of the cylindrical sputtering target 12 with indium drives indium atoms into the surface thereby creating a wetting layer of indium that is bonded to the relevant surface of the backing tube 16 or the cylindrical sputtering target 12. The attachment layer 20 can then adhere to the wetting layer more easily than if it had to adhere directly to the outside surface of the backing tube 16 and the inside surface of the cylindrical sputtering target 12.

In general terms, the cylindrical sputtering target assembly 10 comprises a cylindrical sputtering target having a length greater than approximately thirty-six inches; a cylindrical backing tube; and an attachment layer positioned between the cylindrical sputtering target and the cylindrical backing tube for attaching the cylindrical sputtering target to the cylindrical backing tube. In a preferred embodiment, the attachment layer comprises indium.

The following example is exemplary of the method of the present invention:

### EXAMPLE

A. Preparation of Backing Tube and Ring Targets

1. Clean the outside surface 94 of the backing tube 16 and the inside surface 96 of the cylindrical sputtering target (ring targets 34) 12, such as by wiping with alcohol.

B. Wetting the Inside Surface of the Ring Targets

1. Protect the outside surface of the ring targets 34 (i.e. the sputtering surface 24), for example by covering the outside surface with Kapton™ brand polyimide tape.

2. Blast the inside surfaces 96 of the ring targets, such as with 220 grit silicon carbide.

3. Clean the inside surface 96 of the ring targets again, such as by blowing off the dust with air and then wiping the surface 96 with alcohol.

4. Place a wire heater around a single ring target 34 and cover it with a thermal insulator sheet.

5. Place the single ring target 34 on a hot plate and set the heater coil and hot plate to heat the single ring target to 350° F. (177° C.).

6. Once the single ring target reaches 350° F. (177° C.), apply a measured amount (e.g. 36 grams or one spoon) of indium to the inside surface 96 of the single ring target.

7. While the indium is still at 350° F., coat the entire inside surface 96 of the single ring target 12 with molten indium by spreading the indium over the surface with an ultrasonic tool, such as the ultrasonic horn 100 shown in FIG. 6. While spreading the indium, apply ultrasonic energy to the inside of the single ring target with the ultrasonic tool (horn) to cause the indium to adhere to the single ring target (i.e. to wet the inside surface 96 of the single ring target with indium).

8. While the single ring target is still at 350° F., verify that the entire inside surface of the single ring target has been wetted (coated) with indium, such as by scrapping the surface with a razor blade to make sure that the indium has adhered to the surface and does not come off on the razor blade. Also, visually ensure that there are no areas not coated with indium (dry spots). Then allow the ring target to cool to room temperature.

9. Repeat steps 1-8 for each of the single ring target sections.

C. Wetting the Outside Surface of the Backing Tube

1. Protect the ends of the cylindrical backing tube 16 from contamination, e.g. by covering the ends of the backing tube with Kapton™ brand polyimide tape.

2. Blast the outside surface 94 of the backing tube 16.

3. Clean the outside surface 94 again, such as by air blasting the dust off the outside surface of the backing tube and wiping down the backing tube with alcohol.

4. Place the aluminum heating tube 50 inside the backing tube 16, turn it on and let it heat up to 350° F.

5. Apply a quantity of indium to the outside surface 94 of the backing tube.

6. While the indium is still at 350° F., coat the entire outside surface 94 of the backing tube with molten indium by spreading the indium over the outside surface with an ultrasonic tool (such as the ultrasonic horn 106 shown in FIG. 7). While spreading the indium, apply ultrasonic energy to the ultrasonic tool (horn) to cause the indium to adhere to the backing tube (i.e. to wet the outside surface 94 of the backing tube with indium).

7. While the backing tube is still at 350° F., verify that the entire outside surface of the backing tube has been wetted (coated) with indium, such as by scrapping the surface with a razor blade to make sure that the indium has adhered to the surface and does not expose any of the underlying backing tube. Also, visually ensure that there are no areas not coated with indium (dry spots). Then allow the backing tube to cool to room temperature.

D. Preparing the Ring Targets for Bonding

1. Assemble three ring targets 34 at a time to form a ring target assembly.

2. Establish an approximately 0.02 inch (0.5 mm) gap (i.e. the gap 38) between each two ring targets by placing four long wires (e.g. 0.02 inch/0.5 mm diameter) between each two ring targets, with the wires being approximately equally spaced apart. Cut off each wire flush with the outside and inside surfaces of the ring target and place an inert tape (such as Kapton™ brand polyimide tape) around the inside circumference of the two ring targets over the gap.

3. Inject a water soluble masking material (for example, an acrylic polymer such as WSM-90 available from Contronic Devices Inc., of Huntington Beach, Calif.) in the 0.5 mm gap 38 between each two adjacent ring targets.

4. Place an inert tape (such as Kapton™ brand polyimide tape) around the outside circumference of each two ring targets over the gap 38 filled with water soluble masking material.

5. Place wire heaters around the ring targets 34 and cover them with a thermal insulator blanket.

6. Turn on the heaters and maintain the ring target assembly at an appropriate temperature (125° F./51.7° C. for WSM-90) until the water soluble masking material is cured.

E. Preparing the Backing Tube for Bonding

1. Protect the ends of the backing tube 16 with an inert tape (such as Kapton™ brand polyimide tape).

2. Place four approximately 0.015 inch (0.38 mm) wide wires along the length of the backing tube (preferably, use silver coated copper wire). The four wires are held in place by an inert tape (such as Kapton™ brand polyimide tape). These wires will establish the slot 90 (shown in FIG. 5) between the ring targets 12 and the backing tube 16 where the indium bond will be formed.

F. Bonding the Ring Targets to the Backing Tube (Vertical Assembly of Targets)

1. With the aluminum heating tube 50 still inside of the backing tube, slide the heating tube 54 over the vertical fixture 86 in the assembly stand 80 so that the backing tube 16 is in the vertical position as shown in FIG. 5.

2. Turn on the heaters 60 in the aluminum heating tube 50 and in the ring target assemblies.

3. Once the backing tube 16 and the ring target assemblies have reached 350° F. (177 ° C.), slide one of the ring target assemblies (i.e. three conjoined ring targets 34) over the top of the backing tube 16 until it stops against the surface 74 of the target stop 70 as shown in FIG. 5, or against a previously positioned ring target assembly. The ring target assemblies are not placed over the backing tube when they are cool because of indium's tendency to cold weld to itself. Therefore, the indium is preferably molten so that the components slide over each other during assembly. Typically, the hot ring target assemblies are slid over the backing tube 16 by hand, with thermal gloves protecting the hands.

4. Create a gasket with a suitable material (such as an elastomer like Sylgard(® 184 brand silicone elastomer) around the bottom of the first ring target assembly by injecting the material between the backing tube 16 and the fixture 58 to prevent indium from flowing out the bottom of the slot 90, and allow the gasket to cure. Generally, the gasket will extend upward about 0.125 inches into the slot 90 and an inert tape (such as Kapton™ brand polyimide tape) is used to cover the outside of the gasket.

5. Fill the slot (space) 90 between the ring target assembly and the backing tube with indium and gently tap the target to remove any air bubbles. Generally, this is done by spooning molten indium into the slot 90 while the indium is at its melting point.

6. Repeat steps 3 and 5 with the remaining ring targets until all of the target assemblies have been positioned on the backing tube 16. For example, until the length “h” of the sputtering target 12 (shown in FIG. 2) is greater than thirty-six inches. In a representative example, “h” is approximately ninety-seven (97) inches. Before a second or subsequent ring target assembly (or a single ring target 34) is positioned next to a ring target assembly already positioned around the backing tube 16, a gap is created between the two ring target assemblies by placing several (e.g. four) 0.20 inch wires across the top surface of the already positioned assembly, and creating a gasket with WSM 90, as was described previously in step D(2).

7. In an alternative embodiment, the ring targets 34 are positioned around the backing tube 16 while it is in a horizontal position using the following procedure described below in Section G (Horizontal Assembly of Targets) instead of using the procedure described in this Section F (Vertical Assembly of Targets).

G. Alternative Procedure for Bonding the Ring Targets to the Backing Tube

(Horizontal Assembly of Targets)

1. Instead of using the procedure described above in Section F (Vertical Assembly of Targets), the following procedure can be used in place of Section F. With the aluminum heating tube 50 still inside of the backing tube, lay the backing tube 16 on its side in a horizontal position.

2. Turn on the heaters 60 in the aluminum heating tube 50 and in the ring target assemblies.

3. Create a gasket with WSM 90 around the bottom of the first ring target assembly by injecting the material between the backing tube 16 and the fixture 58 to prevent indium from flowing out the bottom of the slot 90, and allow the gasket to cure.

4. Once the backing tube 16 and the ring target assemblies have reached 350° F. (177 ° C.), and with the backing tube lying horizontally, slide one of the ring target assemblies (i.e. three conjoined ring targets 34) over the top of the backing tube 16 until it stops against the surface 74 of the target stop 70 as shown in FIG. 5 (Alternatively, individual ring targets 34 can be slid over the backing tube 16). The ring target assemblies are not placed over the backing tube when they are cool because of indium's tendency to cold weld to itself. Therefore, the indium is preferably molten so that the components slide over each other during assembly. Typically, the hot ring target assemblies are slid over the backing tube 16 by hand, with thermal gloves protecting the hands.

5. After a first ring target assembly is in position around the backing tube 16, place a spacer block (e.g. a one inch metal block) over the gap 38 (filled with WSM-90) at the end of the first ring target assembly that is not positioned against the surface 74. Then slide a second ring target assembly over the backing tube 16 until it hits the spacer block.

6. Repeat step 5 until all the ring target assemblies have been positioned around the backing tube. Once all the ring target assemblies have been positioned around the backing tube 16, turn off the heaters and allow the ring targets and the backing tube 16 to cool to room temperature. Alternatively, the heaters can be left on and the following step 7 is done with a hot assembly.

7. With the aluminum heating tube 50 still inside of the backing tube 16, slide the heating tube 54 over the vertical fixture 86 in the assembly stand 80 so that the backing tube 16 is in the vertical position as shown in FIG. 5.

8. Turn on the heaters 60 in the aluminum heating tube 50 and in the ring target assemblies (if they were turned off in step 6).

9. Using the space created by the lowest spacer block, fill the slot 90 between the lowest ring target assembly and the backing tube with indium and gently tap the target to remove any air bubbles. Then remove the spacer block and let the two adjacent ring target assemblies slide together along the gap 38.

10. Repeat step 9 until indium has been added to the slot 90 between all of the ring target assemblies and the backing tube 16.

H. Cleaning the Cylindrical Sputtering Target Assembly

1. After one of the procedures described Sections F or G is used, the cylindrical sputtering target assembly 10 is allowed to cool to room temperature. Then lift the cool cylindrical sputtering target assembly 10 off of the vertical fixture 86 of the assembly stand 80 and lay it horizontally on a padded surface.

2. Remove all tape from the outside of the cylindrical sputtering target assembly 10 and remove the aluminum heating tube 50 from the inside of the backing tube 16, and remove the remaining wire heaters and thermal blanket from around the ring targets 34.

3. Use warm water to remove all of the WSM-90 from the cylindrical sputtering target assembly, including from the gaps 38 between the ring targets 34, and also remove the wires that were use to establish the gaps 38.

4. Scuff out all tape stains from the cylindrical sputtering target assembly 10 with a plastic scuff pad.

5. Clean the gaps 38 between the ring targets 34 thoroughly with alcohol.

6. Scuff out all oxidation from the ends of the backing tube using a plastic scuff pad.

7. Scuff the inside of the backing tube 16 with a plastic scuff pad.

8. Wipe the entire cylindrical sputtering target assembly 10 clean with an alcohol wipe.

Although the present invention has been described in terms of the presently preferred embodiments, it is to be understood that such disclosure is not to be interpreted as limiting. Various alterations and modifications will no doubt become apparent to those skilled in the art after having read the above disclosure. Accordingly, it is intended that the appended claims be interpreted as covering all alterations and modifications as fall within the true spirit and scope of the invention.

We claim:

1. A method for attaching a cylindrical sputtering target to a backing tube comprising:
a) preparing an outside surface of a cylindrical backing tube and/or an inside surface of one or more cylindrical sputtering target sections for bonding;
b) bringing the cylindrical backing tube and the one or more cylindrical sputtering target sections together so that the outside surface of the cylindrical backing tube and the inside surface of the one or more cylindrical sputtering target sections are adjacent to each other but separated by a space, with the one or more cylindrical sputtering target sections having a total length greater than thirty-six inches; and
c) filling the space with an attachment material while the backing tube is oriented in a vertical direction, the attachment material being sufficiently strong to keep the one or more cylindrical sputtering target sections attached to the cylindrical backing tube during a sputtering process.

2. The method of claim 1 wherein step “a” comprises wetting the outside surface of a cylindrical backing tube and/or an inside surface of one or more cylindrical sputtering target sections with indium.

3. The method of claim 1 wherein the attachment material comprises indium.

4. The method of claim 1 wherein the total length of the cylindrical sputtering target sections is greater than forty inches.

5. A method for attaching a cylindrical sputtering target to a backing tube comprising:
a) preparing an inside surface of one or more cylindrical sputtering target sections and/or an outside surface of a cylindrical backing tube for bonding;
b) positioning one or more of the cylindrical sputtering target sections around the cylindrical backing tube with a space being left between the inside surface of the one or more cylindrical sputtering target sections and the outside surface of the cylindrical backing tube;
c) filling the space with indium while the cylindrical backing tube is in a vertical orientation; and
d) repeating steps b and c, if necessary, until the one or more cylindrical sputtering target sections form a cylindrical sputtering surface around the cylindrical backing tube having a length greater than thirty-six inches.

6. The method of claim 5 wherein the inside surface of the one or more cylindrical sputtering target sections and/or the outside surface of the cylindrical backing tube are prepared for bonding by wetting with indium.

7. The method of claim 6 wherein ultrasonic energy is used in the wetting with indium step.

8. The method of claim 5 wherein the cylindrical backing tube is in a vertical position when the one or more of the cylindrical sputtering target sections are positioned around the cylindrical backing tube.

9. The method of claim 8 wherein the cylindrical backing tube is positioned on a fixture inserted inside the cylindrical backing tube to maintain the cylindrical backing tube in the vertical position.

10. The method of claim 5 wherein the one or more cylindrical sputtering target sections are heated to a temperature above the melting point of indium while the one or more cylindrical sputtering target sections are being positioned around the cylindrical backing tube.

11. The method of claim 10 wherein the temperature is approximately 350° F. (177 ° C.).

12. The method of claim 5 wherein the cylindrical backing tube is heated to a temperature above the melting point of indium while the one or more cylindrical sputtering target sections are being positioned around the cylindrical backing tube.

13. The method of claim 10 wherein the temperature is approximately 350° F. (177 ° C.).

14. A method for attaching a cylindrical sputtering target to a backing tube comprising:
a) wetting an inside surface of one or more cylindrical sputtering target sections, and an outside surface of a backing tube, with indium;
b) forming a first ring target assembly by connecting two or more of the cylindrical sputtering target sections together;
c) forming one or more additional ring target assemblies by connecting two or more of the cylindrical sputtering target sections together;
d) positioning the first ring target assembly around the backing tube with a first space being left between an inside surface of the ring target assembly and the outside surface of the backing tube;
e) filling the first space with indium while the backing tube is positioned in a vertical position;
f) positioning one of the additional ring target assemblies around the backing tube with a second space being left between the inside surface of the additional ring target assembly and the outside surface of the backing tube;
g) filling the second space with indium while the backing tube is positioned in a vertical position; and
h) repeating steps f and g, if necessary, until the length of the sputtering surface is greater than thirty-six inches.

15. The method of claim 14 wherein ultrasonic energy is used to help with the wetting process.

16. The method of claim 14 wherein steps f and g are repeated until the length of the sputtering surface is greater than forty inches.

17. The method of claim 14 wherein the one or more cylindrical sputtering target sections are heated to a temperature above the melting point of indium while the one or more cylindrical sputtering target sections are being positioned around the cylindrical backing tube.

18. The method of claim 14 wherein the cylindrical backing tube is heated to a temperature above the melting point of indium while the one or more cylindrical sputtering target sections are being positioned around the cylindrical backing tube.

19. A sputtering target assembly comprised of:
a cylindrical sputtering target having a length greater than approximately thirty-six inches and being comprised of one or more cylindrical sputtering target sections;
a cylindrical backing tube positioned inside of the cylindrical sputtering target; and
an attachment layer comprised of indium positioned between the cylindrical sputtering target and the cylindrical backing tube for attaching the cylindrical sputtering target to the cylindrical backing tube.

20. The sputtering target assembly of claim 19 wherein the length of the cylindrical sputtering target is greater than forty inches.

21. The sputtering target assembly of claim 19 wherein the cylindrical sputtering target sections are comprised of a ceramic material.
